(19) United States
(12) Patent Application Publication
(10) Pub. No.: US 2026/0148937 A1
(43) Pub. Date: May 28, 2026

(54) PLASMA PROCESSING APPARATUS AND PLASMA PROCESSING METHOD

(71) Applicant: Tokyo Electron Limited, Tokyo (JP)

(72) Inventors: Yoshikazu OBARA, Miyagi (JP); Yuya WADA, Miyagi (JP); Daiki TABEI, Miyagi (JP); Kazuyasu TSUZUKI, Miyagi (JP); Tejung HUANG, Hsin-chu City (TW); Jianjyun LIAO, Hsin-chu City (TW); Yuchun LAI, Hsin-chu City (TW); Masahiko TAKAHASHI, Miyagi (JP)

(21) Appl. No.: 19/392,977

(22) Filed: Nov. 18, 2025

(30) Foreign Application Priority Data
Nov. 26, 2024 (JP) 2024-205740

(51) Int. Cl. H01J 37/32

(52) U.S. Cl. CPC H01J 37/3211; H01J 37/3266; H01J 37/32834; H01J 2237/334

(57) ABSTRACT

Plasma processing apparatus includes: plasma processing space; antenna; substrate support including bias electrode; gas introducing port supplying processing gas into plasma processing space; first RF generator supplying first RF signal to antenna; second, third RF generators supplying second, third RF signals to bias electrode; gas exhaust regulating plasma processing space pressure; and controller including circuitry. Controller causes: first RF generator to supply first-power-level first RF signal to antenna and second RF generator to supply third-power-level second RF signal to bias electrode; third RF generator to supply fifth-power-level third RF signal to bias electrode; second RF generator to supply fourth-power-level second RF signal to bias electrode; gas exhaust to exhaust plasma processing space gas; first RF generator to supply second-power-level first RF signal to antenna and third RF generator to supply sixth-power-level third RF signal to bias electrode; and third RF generator to supply sixth-power-level third RF signal to bias electrode.

### CROSS-REFERENCE TO RELATED APPLICATION

The present application claims priority under 35 U.S.C. § 119 to Japanese Patent Application No. 2024-205740, filed Nov. 26, 2024, the contents of which are incorporated herein by reference in their entireties.

### BACKGROUND OF THE INVENTION

### Field of the Invention

The present disclosure relates to a plasma processing apparatus and a plasma processing method.

### Description of the Related Art

Japanese Patent Application Laid-Open Publications No. 2022-048032 and No. 2022-048811 disclose a plasma processing apparatus and a plasma processing method for improving the process performance using a plurality of high-frequency power pulse signals.

### SUMMARY OF THE INVENTION

A plasma processing apparatus is provided, which includes: a plasma processing chamber including a plasma processing space; an antenna; a substrate support disposed in the plasma processing chamber, including a bias electrode, and configured to support a substrate; a gas introducing port configured to supply a processing gas into the plasma processing space; a first RF generator configured to supply a first RF signal to the antenna, the first RF signal having different power levels in different time frames; a second RF generator configured to supply a second RF signal to the bias electrode, the second RF signal having different power levels in different time frames; a third RF generator configured to supply a third RF signal to the bias electrode, the third RF signal having different power levels in different time frames; a gas exhaust configured to regulate a pressure in the plasma processing space; and a controller including a circuitry, wherein the controller is configured to perform a process including: causing the first RF generator to supply a first RF signal having a first power level to the antenna and causing the second RF generator to supply a second RF signal having a third power level to the bias electrode; causing the third RF generator to supply a third RF signal having a fifth power level to the bias electrode; causing the second RF generator to supply a second RF signal having a fourth power level to the bias electrode; causing the gas exhaust to exhaust a gas in the plasma processing space; causing the first RF generator to supply a first RF signal having a second power level to the antenna and causing the third RF generator to supply a third RF signal having a sixth power level to the bias electrode; and causing the third RF generator to supply the third RF signal having the sixth power level to the bias electrode without causing the first RF generator to supply the first RF signal having the second power level to the antenna.

### BRIEF DESCRIPTION OF THE DRAWINGS

FIG. 1 is an example of a diagram for explaining a configuration example of a plasma processing system;

FIG. 2 is an example of a diagram for explaining a configuration example of an inductively coupled plasma processing apparatus;

FIG. 3 is a flowchart showing an example of a plasma etching process;

FIG. 4 is a time chart showing an example of a plasma etching process;

FIG. 5A is an example of a schematic cross-sectional view of a substrate;

FIG. 5B is an example of a schematic cross-sectional view of a substrate;

FIG. 6A is a schematic cross-sectional view of a substrate;

FIG. 6B is a schematic cross-sectional view of a substrate;

FIG. 6C is a schematic cross-sectional view of a substrate;

FIG. 6D is a schematic cross-sectional view of a substrate;

FIG. 6E is a schematic cross-sectional view of a substrate; and

FIG. 6F is a schematic cross-sectional view of a substrate.

### DETAILED DESCRIPTION OF THE DISCLOSURE

Hereinafter, various exemplary embodiments will be described in detail with reference to the drawings. In the drawings, the same reference numerals denote the same or corresponding parts.

### Plasma Processing System

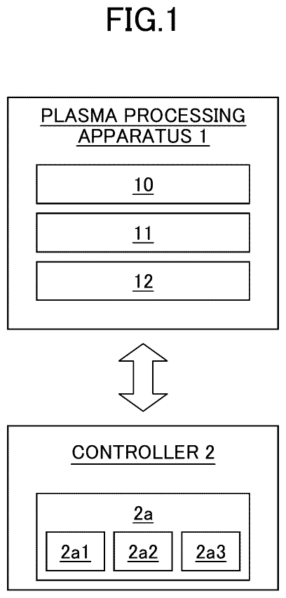

FIG. 1 is an example of a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma forming part 12. The plasma processing chamber 10 includes a plasma processing space. The plasma processing chamber 10 also includes at least one gas supply port for supplying at least one processing gas into the plasma processing space, and at least one gas exhaust port for exhausting a gas from the plasma processing space. The gas supply port is connected to a gas supply 20 described later, and the gas exhaust port is connected to a gas exhaust system 40 described later. The substrate support 11 is disposed in the plasma processing space and has a substrate support surface for supporting a substrate.

The plasma forming part 12 is configured to form a plasma from at least one processing gas supplied into the plasma processing space. The plasma formed in the plasma processing space may be a Capacitively Coupled Plasma (CCP), an Inductively Coupled Plasma (ICP), an Electron Cyclotron Resonance (ECR) Plasma, a Helicon Wave Plasma (HWP), a Surface Wave Plasma (SWP), and the like. Various types of plasma forming parts may also be used, including an Alternating Current (AC) plasma forming part and a Direct Current (DC) plasma forming part. In one embodiment, AC signals (AC power) used in the AC plasma forming part have a frequency in the range of 100 kHz to 10 GHz. Accordingly, AC signals include radio frequency (RF) signals and microwave signals. In one embodiment, RF signals have a frequency in the range of 100 kHz to 150 MHz.

The controller 2 processes computer-executable instructions that cause the plasma processing apparatus 1 to perform the various steps described herein. The controller 2 may be configured to control the components of the plasma processing apparatus 1 to perform the various steps described herein. In one embodiment, a part or the whole of the controller 2 may be included in the plasma processing apparatus 1. The controller 2 is realized by, for example, a computer 2a. The controller 2 may include a processing part 2a1, a memory part 2a2, and a communication interface 2a 3. The functions realized by the processing part 2a1 described herein may be implemented by circuitry or processing circuitry, including general purpose processors, application specific processors, integrated circuits, Application Specific Integrated Circuits (ASICs), Central Processing Units (CPUs), and conventional circuitry programmed to realize the described functions, and/or combinations thereof. Processors are regarded as circuitry or processing circuitry, including transistors and other circuitry. Processors may be programmed processors for executing a program stored in the memory part 2a2. This program may be previously stored in the memory part 2a2, or may be acquired through a medium when necessary. An acquired program is stored in the memory part 2a2, read out from the memory part 2a2, and executed by the processing part 2a1. The medium may be any storage medium readable by the computer 2a, or may be a communication line connected to the communication interface 2a 3. The memory part 2a2 may include a Random Access Memory (RAM), a Read Only Memory (ROM), a Hard Disk Drive (HDD), and a Solid State Drive (SSD), or combinations thereof. The communication interface 2a3 may communicate with the plasma processing apparatus 1 via a communication line, such as a Local Area Network (LAN). In the present disclosure, circuitry, a unit, or a means is a hardware component programmed or configured to perform the described functions. The hardware component may be any hardware component described in the present disclosure or may be any hardware component programmed to realize or known to execute the described functions. When the hardware component is a processor that is regarded to be a circuitry type, the circuitry, means, or unit is a combination of hardware and software used to configure the hardware and/or the processor.

### Plasma Processing Apparatus

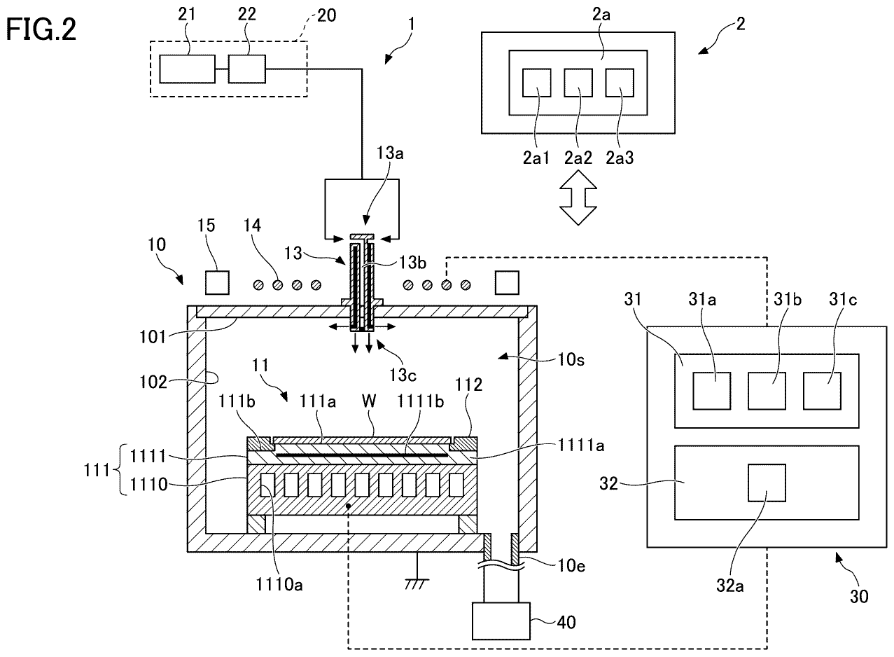

A configuration example of an inductively coupled plasma processing apparatus as an example of the plasma processing apparatus 1 will be described below. FIG. 2 is an example of a diagram for explaining a configuration example of the inductively coupled plasma processing apparatus.

The inductively coupled plasma processing apparatus 1 includes a plasma processing chamber 10, a gas supply 20, a power source system 30, and a gas exhaust system 40. The plasma processing chamber 10 includes a dielectric window 101. The plasma processing apparatus 1 also includes a substrate support 11, a gas introducer, and an antenna 14. The substrate support 11 is disposed in the plasma processing chamber 10. The antenna 14 is disposed on or above the plasma processing chamber 10 (i.e., on or above the dielectric window 101). The plasma processing chamber 10 includes a plasma processing space 10s defined by the dielectric window 101, side walls 102 of the plasma processing chamber 10, and the substrate support 11. The plasma processing chamber 10 is grounded.

The substrate support 11 includes a main part 111 and a ring assembly 112. The main part 111 includes a center region 111a for supporting a substrate W and an annular region 111b for supporting the ring assembly 112. A wafer is an example of the substrate W. The annular region 111b of the main part 111 surrounds the center region 111a of the main part 111 in a plan view. The substrate W is disposed on the center region 111a of the main part 111, and the ring assembly 112 is disposed on the annular region 111b of the main part 111 to surround the substrate W on the center region 111a of the main part 111. Thus, the center region 111a is also referred to as a substrate support surface for supporting the substrate W, and the annular region 111b is also referred to as a ring support surface for supporting the ring assembly 112.

In one embodiment, the main part 111 includes a table 1110 and an electrostatic chuck 1111. The table 1110 includes a conductive member. The conductive member of the table 1110 may function as a bias electrode. The electrostatic chuck 1111 is disposed on the table 1110. The electrostatic chuck 1111 includes a ceramic member 1111a and an electrostatic chuck electrode 1111b disposed in the ceramic member 1111a. The electrostatic chuck electrode 1111b is also referred to as a clamping electrode. In one embodiment, the electrostatic chuck electrode 1111b is electrically connected or coupled to a chuck power source. The chuck power source may be a DC power source or an AC power source. The ceramic member 1111a includes the center region 111a. In one embodiment, the ceramic member 1111a also includes the annular region 111b. Any other member, such as an annular electrostatic chuck or an annular insulating member, that surrounds the electrostatic chuck 1111, may include the annular region 111b. In this case, the ring assembly 112 may be disposed on the annular electrostatic chuck or the annular insulating member, or may be disposed on both the electrostatic chuck 1111 and the annular insulating member. At least one bias electrode electrically connected or coupled to a power source 31 and/or a power source 32 described below may be disposed in the ceramic member 1111a. The conductive member of the table 1110 and the bias electrode in the ceramic member 1111a may function as a plurality of bias electrodes. The electrostatic chuck electrode 1111b may function as a bias electrode. Accordingly, the substrate support 11 includes at least one bias electrode.

The ring assembly 112 includes one or a plurality of annular members. In one embodiment, the one or plurality of annular members include one or a plurality of edge rings and at least one cover ring. The edge rings are composed of a conductive material or an insulating material, and the cover ring is composed of an insulating material.

The substrate support 11 may also include a temperature regulation module configured to regulate at least one of the electrostatic chuck 1111, the ring assembly 112, or the substrate W to a target temperature. The temperature regulation module may include a heater, a heat transfer medium, and a flow path 1110a, or a combination thereof. A heat transfer fluid, such as brine or gas, flows through the flow path 1110a. In one embodiment, the flow path 1110a is formed in the table 1110, and one or a plurality of heaters are disposed in the ceramic member 1111a of the electrostatic chuck 1111. The substrate support 11 may also include a heat transfer gas supply configured to supply a heat transfer gas to a gap between the back surface of the substrate W and the center region 111a.

The gas introducer is configured to introduce at least one processing gas from the gas supply 20 into the plasma processing space 10s. In one embodiment, the gas introducer includes a Center Gas Injector (CGI) 13. The center gas injector 13 is disposed above the substrate support 11, and is attached to a center opening formed in the dielectric window 101. The center gas injector 13 includes at least one gas supply port 13a, at least one gas flow path 13b, and at least one gas introducing port 13c. A processing gas supplied to the gas supply port 13a is introduced into the plasma processing space 10s from the gas introducing port 13c through the gas flow path 13b. In addition to or instead of the center gas injector 13, the gas introducer may include one or a plurality of Side Gas Injectors (SGI) attached to one or a plurality of openings formed in the side walls 102.

The gas supply 20 may include at least one gas source 21 and at least one flow rate controller 22. In one embodiment, the gas supply 20 is configured to supply at least one processing gas from a corresponding gas source 21 into the gas introducer via a corresponding flow rate controller 22. Each flow rate controller 22 may include, for example, a mass flow controller or a pressure-controlled flow rate controller. In addition, the gas supply 20 may include at least one flow rate modulation device that modulates or pulses the flow rate of the at least one processing gas.

The power source system 30 includes the power source 31 that is electrically connected or coupled to the plasma processing chamber 10. In one embodiment, the power source 31 is electrically connected or coupled to the plasma processing chamber 10 via at least one impedance matcher. The impedance matcher may be a mechanically-controlled matcher or an electronically-controlled matcher. The power source 31 is configured to supply at least one RF signal (RF power) to at least one bias electrode and the antenna 14. As a result, a plasma is formed from at least one processing gas supplied into the plasma processing space 10s. Accordingly, the power source 31 may function as at least a part of the plasma forming part 12. By supplying a bias RF signal to at least one bias electrode, which generates a bias potential in the substrate W, it is possible to draw ions in the formed plasma into the substrate W.

The power source 31 includes a first RF generator 31a and a second RF generator 31b. The first RF generator 31a is electrically connected or coupled to the antenna 14, and is configured to generate a source RF signal (source RF power) to form a plasma in the plasma processing space 10s. In one embodiment, the first RF generator 31a is electrically connected or coupled to the antenna 14 via at least one impedance matcher. In one embodiment, the source RF signal has a frequency in the range of 10 MHz to 150 MHz. In one embodiment, the first RF generator 31a may be configured to generate a plurality of source RF signals having different frequencies. One or a plurality of generated source RF signals are supplied to the antenna 14.

The second RF generator 31b is electrically connected or coupled to at least one bias electrode, and is configured to generate a first bias RF signal (first bias RF power). In one embodiment, the second RF generator 31b is electrically connected or coupled to the at least one bias electrode via at least one impedance matcher. The frequency of the first bias RF signal may be the same as or different from the frequency of the source RF signal. In one embodiment, the first bias RF signal has a frequency that is lower than the frequency of the source RF signal. In one embodiment, the first bias RF signal has a frequency in the range of 100 kHz to 60 MHz.

A third RF generator 31c is electrically connected or coupled to at least one bias electrode, and is configured to generate a second bias RF signal (second bias RF power). In one embodiment, the third RF generator 31c is electrically connected or coupled to the at least one bias electrode via at least one impedance matcher. The frequency of the second bias RF signal may be the same as or different from the frequency of the source RF signal. In one embodiment, the second bias RF signal has a frequency lower than the frequency of the source RF signal. The second bias RF signal has a frequency lower than the frequency of the first bias RF signal. In one embodiment, the second bias RF signal has a frequency in the range of 100 kHz to 60 MHz.

In one embodiment, the second RF generator 31b and the third RF generator 31c may be configured to generate a plurality of bias RF signals having different frequencies. That is, the second RF generator 31b may be configured to generate the first bias RF signal and the second bias RF signal. One or a plurality of generated bias RF signals (first bias RF signal, and second bias RF signal) are supplied to at least one bias electrode. In various embodiments, at least one of the source RF signal, or the bias RF signals (first bias RF signal, or second bias RF signal) may be pulsed.

Here, the first rf generator 31a supplies a first rf signal (also referred to as “HF power” in the following description) to the antenna 14 as the source RF signal. It is preferable that the first RF signal has a frequency within the range of, for example, 20 MHz to 60 MHz. Specifically, the first RF signal will be described as one that has a frequency of, for example, 27 MHz.

The second RF generator 31b supplies a second RF signal (also referred to as “LF1 power” in the following description) to the bias electrode of the substrate support 11 as the first bias RF signal. The second RF signal has a frequency lower than the frequency of the first RF signal. It is preferable that the second RF signal has a frequency within the range of, for example, 1 MHz to 15 MHz. Specifically, the second RF signal will be described as one that has a frequency of, for example, 13 MHz.

The third RF generator 31c supplies a third RF signal (also referred to as “LF2 power” in the following description) as the second bias RF signal to the bias electrode of the substrate support 11. The third RF signal has a frequency lower than that of the second RF signal. It is preferable that the third RF signal has a frequency within the range of, for example, 100 kHz to 4 MHz (however, a frequency that is lower than the frequency of the first bias RF signal). Specifically, the third RF signal will be described as one that has a frequency of, for example, 1.2 MHz.

The power source system 30 may also include the power source 32 electrically connected or coupled to the plasma processing chamber 10. The power source 32 includes a voltage generator 32a. In one embodiment, the voltage generator 32a is electrically connected or coupled to at least one bias electrode, and is configured to generate a voltage signal. The generated voltage signal is applied to the at least one bias electrode.

In various embodiments, the voltage signal may be pulsed. In this case, the voltage generator 32a functions as a voltage pulse generator configured to generate a sequence of voltage pulses. Accordingly, a sequence of voltage pulses is applied to the at least one bias electrode. In one embodiment, a sequence of voltage pulses has a plurality of cycles. Each cycle includes a burst of voltage pulses in a first period, and includes a constant reference voltage in a second period. That is, the burst of voltage pulses is repeated in the sequence of voltage pulses. The absolute value of the voltage level of the voltage pulses is greater than the absolute value of the voltage level of the reference voltage. The voltage pulse may be a desired waveform having a rectangular shape, a trapezoidal shape, a triangular shape, or a combination thereof, and the desired waveform may change over time. The voltage pulse may have a positive polarity or a negative polarity. The sequence of voltage pulses may include one or a plurality of positive-polarity voltage pulses and one or a plurality of negative-polarity voltage pulses in one cycle. The voltage generator 32a may be provided by being added to the power source 31, or may be provided in place of the second RF generator 31b.

The antenna 14 includes one or a plurality of coils. In one embodiment, the antenna 14 may include an outer coil and an inner coil that are coaxially arranged. In this case, the power source 31 may be connected to both the outer coil and the inner coil, or to either the outer coil or the inner coil. In the former case, the same RF generator may be connected to both the outer coil and the inner coil, or different RF generators may be connected to the outer coil and the inner coil separately.

A magnetic field generator 15 generates a magnetic field in the plasma processing space 10s. The magnetic field generator 15 is an annular magnet (a permanent magnet, an electromagnet, and the like) concentric with the substrate support 11. The magnetic field generator 15 is disposed on or above the plasma processing chamber 10 (i.e., on or above the dielectric window 101). The magnetic field generator 15 is disposed on the outer side of the antenna 14 in the radial direction of the substrate support 11.

The magnetic field generated in the plasma processing space 10s by the magnetic field generator 15 causes a cyclotron motion in the electrons in a plasma. Thus, the electrons are trapped in the plasma and the electron density of the plasma increases. Thus, the plasma maintaining stability is improved. In other words, the pressure range in which the plasma can be stably formed is increased.

The gas exhaust system 40 may be connected, for example, to a gas outlet 10e provided in the bottom of the plasma processing chamber 10. The gas exhaust system 40 may include a pressure regulating valve and a vacuum pump. The pressure regulating valve regulates the pressure in the plasma processing space 10s. The vacuum pump may include a turbomolecular pump, a dry pump, or a combination thereof.

### Plasma Etching Process

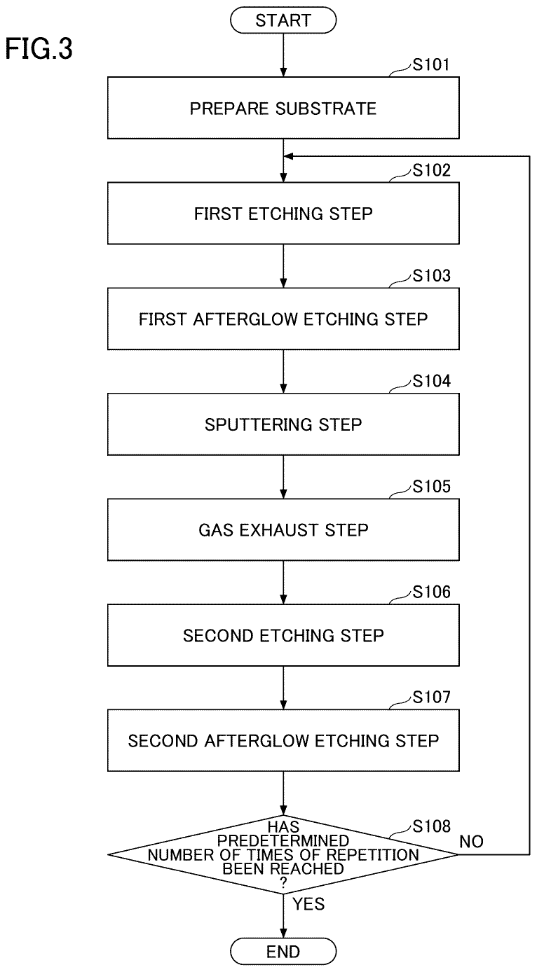

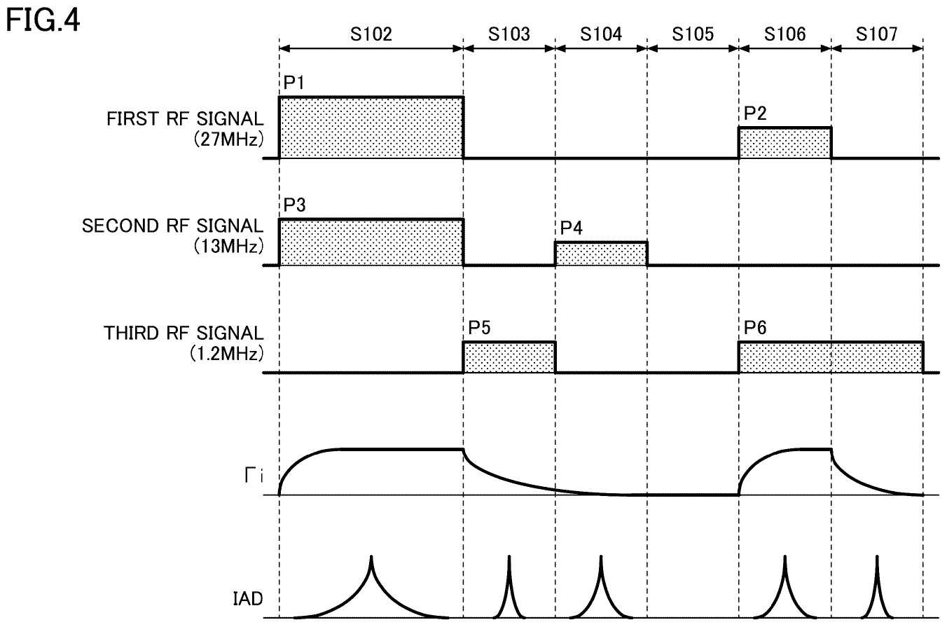

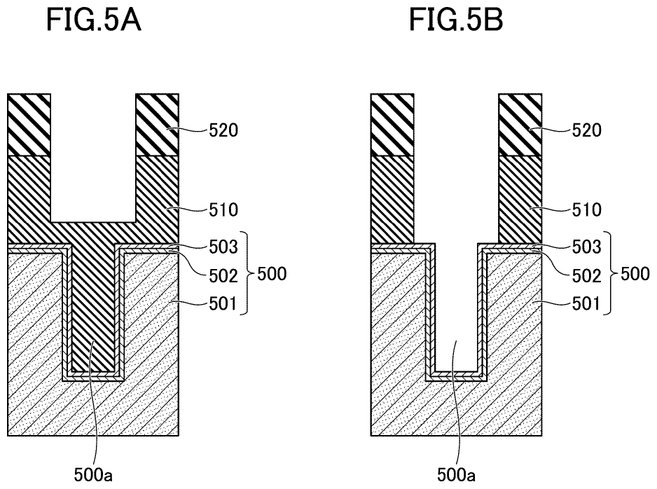

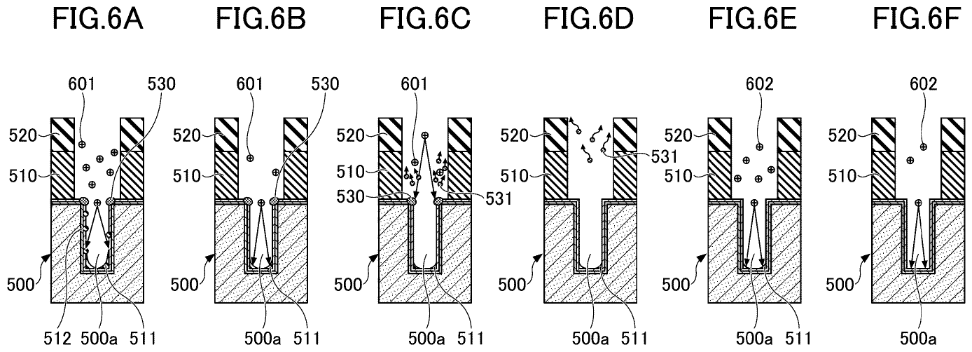

Next, an example of a plasma etching process will be described with reference to FIGS. 3 to 6. FIG. 3 is a flowchart showing an example of the plasma etching process. FIG. 4 is a time chart showing an example of the plasma etching process. FIG. 4 shows a time chart of the power of the first RF signal, the power of the second RF signal, the power of the third RF signal, and the ion flux Γi drawn into the substrate W. In FIG. 4, IAD is a graph schematically showing the ion angle distribution in each of step S102 to S107. In IAD, the horizontal axis represents the ion angle, and the vertical axis represents the frequency. FIGS. 5A, 5B, and 6A to 6F are examples of schematic cross-sectional views of the substrate W.

First, the configuration of the substrate W before starting the plasma etching process will be described with reference to FIG. 5A. FIG. 5A is an example of a schematic cross-sectional view of the substrate W before starting the plasma etching process shown in FIGS. 3 and 4. The substrate W includes a foundation film 500, a carbon-containing film (etching-target film) 510, and a mask 520.

The foundation film 500 includes a recess 500a. In the example shown in FIGS. 5A and 5B, the foundation film 500 includes, for example, a base material 501, a first film 502 formed to cover the surface of the base material 501, and a second film 503 formed to cover the surface of the first film 502. The side wall and the bottom surface of the recess 500a are covered with the first film 502 and the second film 503. For example, the second film 503 has an etching resistance to a plasma of a processing gas described later, as compared with the carbon-containing film 510.

Although the foundation film 500 has been described as being covered with the first film 502 and the second film 503, the present invention is not limited to this configuration. The side wall and the bottom surface of the recess 500a of the foundation film 500 may be covered with one of the first film 502 or the second film 503. The side wall and the bottom surface of the recess 500a of the foundation film 500 do not need to be covered with the first film 502 and the second film 503. The side wall and the bottom surface of the recess 500a of the foundation film 500 may be covered with a plurality of films.

The carbon-containing film 510 is, for example, an organic film. The carbon-containing film 510 is embedded in the recess 500a of the foundation film 500. The carbon-containing film 510 is also formed on the upper surface of the foundation film 500.

The mask 520 has a pattern of an opening and is formed on the carbon-containing film 510. For example, compared with the carbon-containing film 510, the mask 520 has an etching resistance to a plasma of a processing gas described later.

As shown in FIG. 5A, the recess 500a of the foundation film 500 is disposed under an opening of the mask 520. The width of the recess 500a is narrower than the opening width of the mask 520. Further, as shown in FIG. 5A, the carbon-containing film 510 formed on the upper surface of the foundation film 500 may be etched through the opening of the mask 520.

Next, the configuration of the substrate W after the plasma etching process will be described with reference to FIG. 5B. FIG. 5B is an example of a schematic cross-sectional view of the substrate W after the plasma etching process shown in FIGS. 3 and 4. As shown in FIG. 5B, the carbon-containing film 510 is etched through the mask 520 having the pattern of an opening. The carbon-containing film 510 in the recess 500a is also removed.

Here, when the opening width of the recess 500a is narrow (for example, approximately 1 nm to 2 nm), it is difficult for ions to reach the bottom of the recess 500a. Further, accumulation of any deposits near the opening of the recess 500a inhibits etching of the carbon-containing film 510 in the recess 500a. As a result, there is a possibility that a residue of the carbon-containing film 510 remains in the corners between the side wall and the bottom surface of the recess 500a.

Hereinafter, the plasma etching process for improving the residue removing performance will be described with reference to FIGS. 3 to 6.

In step S101, the substrate W is prepared. First, the controller 2 controls the conveying device (not shown) to place the substrate W shown in FIG. 5A on the substrate support 11. Further, the controller 2 controls the gas exhaust system 40 to regulate the pressure in the plasma processing space 10s to a predetermined pressure. The pressure in the plasma processing space 10s is preferably 15m Torr or lower. In the subsequent steps (S102 to S108), the pressure in the plasma processing space 10s is also regulated to a predetermined pressure.

In step S102, a first etching step is performed. The first etching step is an etching step in which a plasma of a processing gas is formed. Here, the controller 2 controls the gas supply 20 to supply a predetermined processing gas (etching gas) from the center gas injector 13 into the plasma processing space 10s. As the processing gas (etching gas), for example, a mixed gas of H₂ gas and N₂ gas is supplied. The controller 2 also controls the power source system 30 to supply the first RF signal (HF power) having a first power level P1 from the first RF generator 31a to the antenna 14, and to supply the second RF signal (LF1 power) having a third power level P3 from the second RF generator 31b to the bias electrode of the substrate support 11. The first power level P1 is preferably 2,000 W or higher, for example.

As shown in FIG. 4, in response to supplying the first RF signal for plasma formation to the antenna 14, the ion flux Γi increases and becomes substantially constant.

FIG. 6A is an example of a schematic cross-sectional view of the substrate W in step S102. By supplying the first RF signal (HF power) having the first power level P1 to the antenna 14, a plasma of the processing gas is formed in the plasma processing space 10s. In addition, by supplying the second RF signal (LF1 power) having the third power level P3 to the bias electrode of the substrate support 11, processing gas ions 601 generated by the plasma are drawn into the substrate W, to etch the carbon-containing film 510 in the recess 500a. Thus, the carbon-containing film 510 is etched through the mask 520 having the pattern of an opening. The carbon-containing film 510 in the recess 500a is also removed.

Here, a reaction sub-product (by-product) 512 generated when the carbon-containing film 510 is etched is deposited near the opening of the recess 500a to form a deposit 530. Thus, the opening width of the recess 500a is narrowed. In addition, a residue 511 of the carbon-containing film 510 remains at the corners between the side wall and the bottom surface in the recess 500a.

In step S103, a first afterglow etching step is performed. The first afterglow etching step is an etching step performed after the first etching step in which the plasma is formed. Here, the controller 2 controls the gas supply 20 to supply the predetermined processing gas (etching gas) from the center gas injector 13 into the plasma processing space 10s continuously from step S102. The controller 2 also controls the power source system 30 to supply the third RF signal (LF2 power) having a fifth power level P5 from the third RF generator 31c to the bias electrode of the substrate support 11.

As shown in FIG. 4, by stopping the supply of the first RF signal for plasma formation, the ion flux Γi decreases.

FIG. 6B is a schematic cross-sectional view of the substrate W in step S103. By supplying the third RF signal (LF2 power) having the fifth power level P5 to the bias electrode of the substrate support 11, the processing gas ions 601 generated by the plasma in step S102 are drawn into the substrate W to etch the carbon-containing film 510 in the recess 500a. Here, the distribution of IAD in step S103 is narrower than the distribution of IAD in step S102. Therefore, the ions 601 enter the substrate W substantially perpendicular to the substrate W and reach the bottom surface of the recess 500a. Therefore, the residue 511 in the recess 500a is removed by etching.

In step S104, a sputtering step is performed. Here, the controller 2 controls the gas supply 20 to supply the predetermined processing gas (etching gas) from the center gas injector 13 into the plasma processing space 10s continuously from step S102. The controller 2 also controls the power source system 30 to supply the second RF signal (LF1 power) having a fourth power level P4 from the second RF generator 31b to the bias electrode of the substrate support 11. Here, the fourth power level P4 of the second RF signal is lower than the third power level P3.

As shown in FIG. 4, by continuing stoppage of the supply of the first RF signal for plasma formation, the ion flux Γi further decreases.

FIG. 6C is a schematic cross-sectional view of the substrate W in step S104. By supplying the second RF signal (LF1 power) having the fourth power level P4 to the bias electrode of the substrate support 11, the processing gas ions 601 generated by the plasma in step S102 are drawn into the substrate W. Here, the distribution of IAD in step S104 is wider than the distribution of IAD in step S103. Thus, the deposit 530 accumulated near the opening of the recess 500a is removed by releasing particles 531 of the reaction by-product by sputtering with the ions 601.

In step S105, a gas exhaust step is performed. Here, the controller 2 controls the gas supply 20 to supply the predetermined processing gas (etching gas) from the center gas injector 13 into the plasma processing space 10s continuously from step S102.

FIG. 6D is a schematic cross-sectional view of the substrate W in step S105. Here, the sputtered reaction by-product particles 531 and the like are exhausted to the outside of the plasma processing chamber 10 together with the processing gas.

In step S106, a second etching step is performed. The second etching step is an etching step in which a plasma of the processing gas is formed. Here, the controller 2 controls the gas supply 20 to supply the predetermined processing gas (etching gas) from the center gas injector 13 into the plasma processing space 10s continuously from step S102. The controller 2 also controls the power source system 30 to supply the first RF signal (HF power) having a second power level P2 from the first RF generator 31a to the antenna 14, and to supply the third RF signal (LF2 power) having a sixth power level P6 from the third RF generator 31c to the bias electrode of the substrate support 11. Here, the second power level P2 of the first RF signal is lower than the first power level P1. The sixth power level P6 of the third RF signal may be equal to the fifth power level P5, may be lower than the fifth power level P5, or may be higher than the fifth power level P5.

As shown in FIG. 4, by supplying the first RF signal for plasma formation to the antenna 14, the ion flux Γi increases and becomes substantially constant.

FIG. 6E is a schematic cross-sectional view of the substrate W in step S106. The first RF signal (HF power) having the second power level P2 is supplied to the antenna 14 to form a plasma of the processing gas in the plasma processing space 10s. In addition, the third RF signal (LF2 power) having the sixth power level P6 is supplied to the bias electrode of the substrate support 11 to draw processing gas ions 602 generated by the plasma into the substrate W, thereby etching the carbon-containing film 510 in the recess 500a. Here, the distribution of IAD in step S106 is narrower than the distribution of IAD in step S102. Therefore, the ions 602 enter the substrate W substantially perpendicularly to the substrate W and reach the bottom surface of the recess 500a. Therefore, the residue 511 in the recess 500a is further removed by etching.

Further, by setting the first RF signal (HF power) to be supplied to the antenna 14 to the second power level P2 that is lower than the first power level P1, the deposit 530 is suppressed from being accumulated near the opening of the recess 500a.

In step S107, a second afterglow etching step is performed. The second afterglow etching step is an etching step performed after the second etching step in which the plasma is formed. Here, the controller 2 controls the gas supply 20 to supply the predetermined processing gas (etching gas) from the center gas injector 13 into the plasma processing space 10s continuously from step S102. The controller 2 also controls the power source system 30 to supply the third RF signal (LF2 power) having the sixth power level P6 from the third RF generator 31c to the bias electrode of the substrate support 11.

As shown in FIG. 4, by stopping the supply of the first RF signal for plasma formation, the ion flux Γi decreases.

FIG. 6F is a schematic cross-sectional view of the substrate W in step S107. By supplying the third RF signal (LF2 power) having the sixth power level P6 to the bias electrode of the substrate support 11, the processing gas ions 602 generated by the plasma in step S106 are drawn into the substrate W to etch the carbon-containing film 510 in the recess 500a. Here, the distribution of IAD in step S107 is narrower than the distribution of IAD in step S102. Therefore, the ions 602 enter the substrate W substantially perpendicular to the substrate W and reach the bottom surface of the recess 500a. Therefore, the residue 511 in the recess 500a is further removed by etching.

In step S108, regarding the steps from step S102 to step S107 as one cycle, the controller 2 determines whether or not a predetermined number of times of repetition of this cycle has been reached. When the predetermined number of times of repetition has not been reached (S108·NO), the process of the controller 2 returns to step S102, to repeat the cycle. When the number of times of repetition has been reached (S108 ·YES), the etching process is ended.

Thereafter, the controller 2 controls the conveying device (not shown) to unload the substrate W shown in FIG. 5B from the substrate support 11.

As described above, in the first etching step (S102), the ion flux Γi is generated and the carbon-containing film 510 in the recess 500a is etched. In the first afterglow etching step (S103), the residue 511 of the carbon-containing film formed at the corners between the side wall and the bottom surface of the recess 500a is removed (etched). In the sputtering step (S104), the deposit 530 accumulated near the opening of the recess 500a is removed by sputtering with the ions 601. In the gas exhaust step (S105), the particles 531 of the reaction by-product are exhausted. In the second etching step (S106), the ion flux Γi is generated and the residue 511 of the carbon-containing film formed at the corners between the side wall and the bottom surface of the recess 500a is removed (etched). In the second afterglow etching step (S107), the residue 511 of the carbon-containing film formed at the corners between the side wall and the bottom surface of the recess 500a is removed (etched).

According to the plasma etching process shown in FIGS. 3 to 6, the removal performance of the residue 511 in the recess 500a can be improved. In particular, even when the opening width of the recess 500a is narrow (for example, approximately 1 nm to 2 nm), the residue 511 of the carbon-containing film can be inhibited from remaining at the corners between the side wall and the bottom surface of the recess 500a.

Further, by regulating the pressure in the plasma processing space 10s to 15 mTorr or lower, it is possible to inhibit redeposition of the particles 531 of the reaction by-product sputtered in step S104. That is, the removal performance of the deposit 530 can be improved.

Further, regulating the pressure in the plasma processing space 10s to 15 mTorr or lower has a risk of reducing the plasma maintaining stability when a plasma is formed in steps S102 and S106. On the other hand, by forming a magnetic field in the plasma processing space 10s by the magnetic field generator 15, it is possible to cause a cyclotron motion of electrons, and to increase the electron density of the plasma. Thus, the plasma maintaining stability can be improved.

Although the embodiment and other particulars of the plasma processing system have been described above, the present disclosure is not limited to the above-described embodiment and other particulars, and various modifications and improvements are applicable within the scope of the spirit of the present disclosure described in the claims.

According to one aspect, it is possible to provide a plasma processing apparatus and a plasma processing method that improve a residue removing performance.

The embodiment disclosed above includes, for example, the following aspects.

### Clause 1

A plasma processing apparatus, including:
a plasma processing chamber including a plasma processing space;
an antenna;
a substrate support disposed in the plasma processing chamber, including a bias electrode, and configured to support a substrate;
a gas introducing port configured to supply a processing gas into the plasma processing space;
a first RF generator configured to supply a first RF signal to the antenna, the first RF signal having different power levels in different time frames;
a second RF generator configured to supply a second RF signal to the bias electrode, the second RF signal having different power levels in different time frames;
a third RF generator configured to supply a third RF signal to the bias electrode, the third RF signal having different power levels in different time frames;
a gas exhaust configured to regulate a pressure in the plasma processing space; and
a controller including a circuitry,
wherein the controller is configured to perform a process comprising:
causing the first RF generator to supply a first RF signal having a first power level to the antenna and causing the second RF generator to supply a second RF signal having a third power level to the bias electrode;
causing the third RF generator to supply a third RF signal having a fifth power level to the bias electrode;
causing the second RF generator to supply a second RF signal having a fourth power level to the bias electrode;
causing the gas exhaust to exhaust a gas in the plasma processing space;
causing the first RF generator to supply a first RF signal having a second power level to the antenna and causing the third RF generator to supply a third RF signal having a sixth power level to the bias electrode; and
causing the third RF generator to supply the third RF signal having the sixth power level to the bias electrode without causing the first RF generator to supply the first RF signal having the second power level to the antenna.

### Clause 2

The plasma processing apparatus according to Clause 1,
wherein the second RF signal having the third power level and the second RF signal having the fourth power level have a frequency that is lower than a frequency of the first RF signal having the first power level and the first RF signal having the second power level, and
the third RF signal having the fifth power level and the third RF signal having the sixth power level have a frequency that is lower than the frequency of the second RF signal having the third power level and the second RF signal having the fourth power level.

### (Clause 3

The plasma processing apparatus according to Clause 1 or 2,
wherein the second power level is lower than the first power level.

### (Clause 4

The plasma processing apparatus according to any one of Clauses 1 to 3,
wherein the fourth power level is lower than the third power level.

### (Clause 5

The plasma processing apparatus according to any one of Clauses 1 to 4,
wherein the pressure in the plasma processing space is 15 mTorr or lower throughout the process.

### (Clause 6

The plasma processing apparatus according to any one of Clauses 1 to 5, further including:
a magnetic field generator configured to generate a magnetic field in the plasma processing space.

### Clause 7

A plasma processing method of a plasma processing apparatus including: a plasma processing chamber including a plasma processing space; an antenna; a substrate support disposed in the plasma processing chamber, including a bias electrode, and configured to support a substrate; a gas introducing port configured to supply a processing gas into the plasma processing space; a first RF generator configured to supply a first RF signal to the antenna, the first RF signal having different power levels in different time frames; a second RF generator configured to supply a second RF signal to the bias electrode, the second RF signal having different power levels in different time frames; a third RF generator configured to supply a third RF signal to the bias electrode, the third RF signal having different power levels in different time frames; and a gas exhaust configured to regulate a pressure in the plasma processing space, the plasma processing method including a process including:
preparing a substrate;
supplying a first RF signal having a first power level to the antenna and supplying a second RF signal having a third power level to the bias electrode;
supplying a third RF signal having a fifth power level to the bias electrode;
supplying a second RF signal having a fourth power level to the bias electrode;
exhausting a gas in the plasma processing space;
supplying a first RF signal having a second power level to the antenna and supplying a third RF signal having a sixth power level to the bias electrode; and
supplying the third RF signal having the sixth power level to the bias electrode without supplying the first RF signal having the second power level to the antenna.

### Clause 8

The plasma processing method according to Clause 7,
wherein the second RF signal having the third power level and the second RF signal having the fourth power level have a frequency that is lower than a frequency of the first RF signal having the first power level and the first RF signal having the second power level, and
the third RF signal having the fifth power level and the third RF signal having the sixth power level have a frequency that is lower than the frequency of the second RF signal having the third power level and the second RF signal having the fourth power level.

### Clause 9

The plasma processing method according to Clause 7 or 8,
wherein the second power level is lower than the first power level.

### Clause 10

The plasma processing method according to any one of Clauses 7 to 9,
wherein the fourth power level is lower than the third power level.

### Clause 11

The plasma processing method according to any one of Clauses 7 to 10,
wherein the pressure in the plasma processing space is 15 mTorr or lower throughout the process.

### Clause 12

The plasma processing method according to any one of Clauses 7 to 11, further including:
generating a magnetic field in the plasma processing space.

### Clause 13

The plasma processing method according to any one of Clauses 7 to 12,
wherein the substrate includes a recess and an etching-target film embedded in the recess.

### Clause 14

The plasma processing apparatus according to any one of Clauses 1 to 6,
wherein the supplying of the first RF signal having the first power level occurs before the supplying of the first RF signal having the second power level.

### Clause 15

The plasma processing apparatus according to any one of Clauses 1 to 6 and 14,
wherein the supplying of the second RF signal having the third power level occurs before the supplying of the second RF signal having the fourth power level.

### Clause 16

The plasma processing apparatus according to any one of Clauses 1 to 6, 14, and 15,
wherein the supplying of the third RF signal having the fifth power level occurs before the supplying of the third RF signal having the sixth power level.

### Clause 17

The plasma processing method according to any one of Clauses 7 to 13,
wherein the supplying of the first RF signal having the first power level occurs before the supplying of the first RF signal having the second power level.

### Clause 18

The plasma processing method according to any one of Clauses 7 to 13 and 17,
wherein the supplying of the second RF signal having the third power level occurs before the supplying of the second RF signal having the fourth power level.

### Clause 19

The plasma processing method according to any one of Clauses 7 to 13, 17, and 18,
wherein the supplying of the third RF signal having the fifth power level occurs before the supplying of the third RF signal having the sixth power level.

What is claimed is:

1. A plasma processing apparatus, comprising:
a plasma processing chamber including a plasma processing space;
an antenna;
a substrate support disposed in the plasma processing chamber, including a bias electrode, and configured to support a substrate;
a gas introducing port configured to supply a processing gas into the plasma processing space;
a first RF generator configured to supply a first RF signal to the antenna, the first RF signal having different power levels in different time frames;
a second RF generator configured to supply a second RF signal to the bias electrode, the second RF signal having different power levels in different time frames;
a third RF generator configured to supply a third RF signal to the bias electrode, the third RF signal having different power levels in different time frames;
a gas exhaust configured to regulate a pressure in the plasma processing space; and
a controller including a circuitry,
wherein the controller is configured to perform a process comprising:
causing the first RF generator to supply a first RF signal having a first power level to the antenna and causing the second RF generator to supply a second RF signal having a third power level to the bias electrode;
causing the third RF generator to supply a third RF signal having a fifth power level to the bias electrode;
causing the second RF generator to supply a second RF signal having a fourth power level to the bias electrode;
causing the gas exhaust to exhaust a gas in the plasma processing space;
causing the first RF generator to supply a first RF signal having a second power level to the antenna and causing the third RF generator to supply a third RF signal having a sixth power level to the bias electrode; and
causing the third RF generator to supply the third RF signal having the sixth power level to the bias electrode without causing the first RF generator to supply the first RF signal having the second power level to the antenna.

2. The plasma processing apparatus according to claim 1,
wherein the second RF signal having the third power level and the second RF signal having the fourth power level have a frequency that is lower than a frequency of the first RF signal having the first power level and the first RF signal having the second power level, and
the third RF signal having the fifth power level and the third RF signal having the sixth power level have a frequency that is lower than the frequency of the second RF signal having the third power level and the second RF signal having the fourth power level.

3. The plasma processing apparatus according to claim 1,
wherein the second power level is lower than the first power level.

4. The plasma processing apparatus according to claim 1,
wherein the fourth power level is lower than the third power level.

5. The plasma processing apparatus according to claim 1,
wherein the pressure in the plasma processing space is 15 mTorr or lower throughout the process.

6. The plasma processing apparatus according to claim 1, further comprising:
a magnetic field generator configured to generate a magnetic field in the plasma processing space.

7. A plasma processing method of a plasma processing apparatus comprising: a plasma processing chamber including a plasma processing space; an antenna; a substrate support disposed in the plasma processing chamber, including a bias electrode, and configured to support a substrate; a gas introducing port configured to supply a processing gas into the plasma processing space; a first RF generator configured to supply a first RF signal to the antenna, the first RF signal having different power levels in different time frames; a second RF generator configured to supply a second RF signal to the bias electrode, the second RF signal having different power levels in different time frames; a third RF generator configured to supply a third RF signal to the bias electrode, the third RF signal having different power levels in different time frames; and a gas exhaust configured to regulate a pressure in the plasma processing space, the plasma processing method including a process comprising:
preparing a substrate;
supplying a first RF signal having a first power level to the antenna and supplying a second RF signal having a third power level to the bias electrode;
supplying a third RF signal having a fifth power level to the bias electrode;
supplying a second RF signal having a fourth power level to the bias electrode;
exhausting a gas in the plasma processing space;
supplying a first RF signal having a second power level to the antenna and supplying a third RF signal having a sixth power level to the bias electrode; and
supplying the third RF signal having the sixth power level to the bias electrode without supplying the first RF signal having the second power level to the antenna.

8. The plasma processing method according to claim 7,
wherein the second RF signal having the third power level and the second RF signal having the fourth power level have a frequency that is lower than a frequency of the first RF signal having the first power level and the first RF signal having the second power level, and
the third RF signal having the fifth power level and the third RF signal having the sixth power level have a frequency that is lower than the frequency of the second RF signal having the third power level and the second RF signal having the fourth power level.

9. The plasma processing method according to claim 7,
wherein the second power level is lower than the first power level.

10. The plasma processing method according to claim 7,
wherein the fourth power level is lower than the third power level.

11. The plasma processing method according to claim 7,
wherein the pressure in the plasma processing space is 15 mTorr or lower throughout the process.

12. The plasma processing method according to claim 7, further comprising:
generating a magnetic field in the plasma processing space.

13. The plasma processing method according to claim 7,
wherein the substrate includes a recess and an etching-target film embedded in the recess.

14. The plasma processing apparatus according to claim 1,
wherein the supplying of the first RF signal having the first power level occurs before the supplying of the first RF signal having the second power level.

15. The plasma processing apparatus according to claim 1,
wherein the supplying of the second RF signal having the third power level occurs before the supplying of the second RF signal having the fourth power level.

16. The plasma processing apparatus according to claim 1,
wherein the supplying of the third RF signal having the fifth power level occurs before the supplying of the third RF signal having the sixth power level.

17. The plasma processing method according to claim 7,
wherein the supplying of the first RF signal having the first power level occurs before the supplying of the first RF signal having the second power level.

18. The plasma processing method according to claim 7,
wherein the supplying of the second RF signal having the third power level occurs before the supplying of the second RF signal having the fourth power level.

19. The plasma processing method according to claim 7,
wherein the supplying of the third RF signal having the fifth power level occurs before the supplying of the third RF signal having the sixth power level.
